(19) United States
(12) Patent Application Publication
(10) Pub. No.: US 2022/0044849 A1
(43) Pub. Date: Feb. 10, 2022

(54) CIRCUIT SUBSTRATE

(71) Applicant: KOA CORPORATION, Nagano (JP)

(72) Inventor: Satoshi KANEGAE, Nagano (JP)

(73) Assignee: KOA CORPORATION, Nagano (JP)

(21) Appl. No.: 17/387,349

(22) Filed: Jul. 28, 2021

(30) Foreign Application Priority Data
Aug. 5, 2020 (JP) 2020-133049

(51) Int. Cl. H01C 7/00; H01C 1/01; H01C 1/14

(52) U.S. Cl. CPC H01C 7/006; H01C 1/14; H01C 1/01

(57) ABSTRACT

Particularly, it is an object to provide a circuit substrate that can reduce a field intensity near an electrode having a high potential. A circuit substrate of the present invention includes an insulated substrate, a thin-film resistive element, and electrodes electrically connected to both sides of the thin-film resistive element, the thin-film resistive element and the electrodes being disposed on a surface of the insulated substrate. The circuit substrate is characterized in that the thin-film resistive element has a pattern in which a resistance wire is repeatedly folded back, and a dummy wire for reducing a field intensity is provided on a high-potential electrode side.

### TECHNICAL FIELD

The present invention relates to a circuit substrate including a thin-film resistive element on an insulated substrate.

### BACKGROUND ART

A circuit substrate applied to a thin-film resistor includes a thin-film resistive element having a predetermined pattern by vapor deposition or a photolithographic technique. The thin-film resistive element has a repeated fold-back pattern (which may also be called a meander pattern) (see Patent Literature 1). Electrodes are electrically connected to both ends of the thin-film resistive element.

### CITATION LIST

### Patent Literature

[Patent Literature 1] Japanese Patent Laid-Open No. 2009-130174

### SUMMARY OF INVENTION

### Problem to be Solved by the Invention

By the way, a field intensity near an electrode having a high potential increases in a conventional thin-film resistive element, and as a result, the temporal changes of the resistance value become large, which disadvantageously reduces the product life.

Accordingly, the present invention has been made in view of the above problem, and particularly, it is an object of the present invention to provide a circuit substrate that can reduce a field intensity near an electrode having a high potential.

### Means for Solving the Problem

The present invention is a circuit substrate including an insulated substrate, a thin-film resistive element, and electrodes electrically connected to both sides of the thin-film resistive element, the thin-film resistive element and the electrodes being disposed on a surface of the insulated substrate, characterized in that the thin-film resistive element has a pattern in which a resistance wire is repeatedly folded back, and a dummy wire for reducing a field intensity is provided on a high-potential electrode side.

According to the present invention, the dummy wire is preferably provided continuously to the fold-back pattern of the resistance wire. For example, a form can be exemplified in which the dummy wire is folded back to outside from the resistance wire positioned outermost of the fold-back pattern.

Furthermore, according to the present invention, the dummy wire preferably branches off from the resistance wire. For example, a form can be exemplified in which the dummy wire branches off from a fold vertex of the resistance wire.

According to the present invention, a plurality of the dummy wires are preferably provided.

### Advantageous Effect of Invention

According to the present invention, a dummy wire is disposed on a side having an electrode having a high potential so that a field intensity can be reduced. Thus, temporal changes of the resistance value can be reduced, and an increase in product life can be attempted.

### BRIEF DESCRIPTION OF DRAWINGS

FIG. 1 is a plan view of a thin-film resistive element according to a first embodiment of the present invention.

FIG. 2 is a partially enlarged plan view showing an enlarged part of the thin-film resistive element in FIG. 1.

FIG. 3(a) is a partially enlarged plan view showing an enlarged part enclosed by a dashed line in FIG. 1. FIG. 3(b) is a potential distribution diagram on a measurement line for potential/field intensity shown in FIG. 3(a), and FIG. 3(c) is a field intensity distribution diagram.

FIG. 4 is a plan view of a thin-film resistive element according to a second embodiment of the present invention.

FIG. 5(a) is a partially enlarged plan view showing an enlarged part enclosed by a dashed line in FIG. 4. FIG. 5(b) is a potential distribution diagram at a measurement point for potential/field intensity shown in FIG. 5(a), and FIG. 5(c) is a field intensity distribution diagram.

FIG. 6 is a graph showing a relationship between evaluation time and AR in humidity load life tests according to an example and a comparison example.

FIG. 7 is a partial cross-sectional view of a thin-film resistor including a circuit substrate of an embodiment.

FIG. 8 is a plan view of a thin-film resistive element according to a comparison example.

### MODE FOR CARRYING OUT THE INVENTION

Embodiments of the present invention (hereinafter, each simply called “embodiment”) are described in detail below. It should be noted that the present invention is not limited to the following embodiments, but various changes can be made thereto without departing from the spirit and scope.

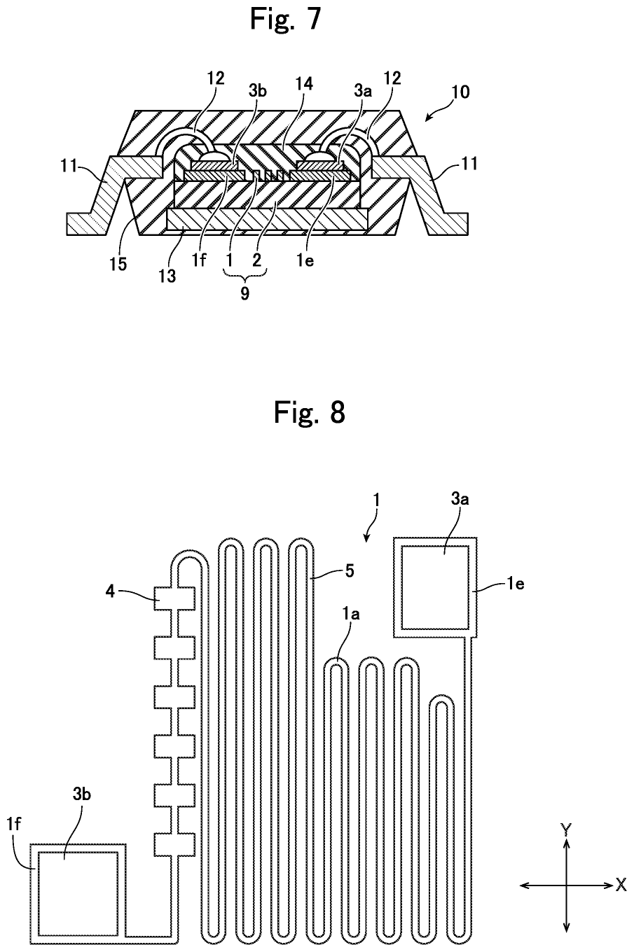

A circuit substrate according to an embodiment is applied to a chip resistor, a resistance network and the like, and for example, a thin-film resistor 10 including the circuit substrate according to the embodiment has a cross section shown in FIG. 7.

As shown in FIG. 7, reference numeral “2” denotes an insulated substrate, and a thin-film resistive element 1 having a pattern in which a resistance wire is repeatedly folded back is provided on a surface of the insulated substrate 2. Wide parts 1e and 1f are provided on both ends of the thin-film resistive element 1. Electrodes 3a and 3b are provided on surfaces of the wide parts 1e and 1f, respectively, and the thin-film resistive element 1 and the electrodes 3a and 3b are electrically connected. As shown in FIG. 7, the electrodes 3a and 3b and terminals 11 are electrically connected via wires 12. A die pad 13 is provided on a back surface of the insulated substrate 2. The terminals 11 and the die pad 13 construct a lead frame.

It should be noted that a circuit substrate 9 includes the insulated substrate 2, the thin-film resistive element 1 and the electrodes 3a and 3b.

As shown in FIG. 7, the surfaces of the thin-film resistive element 1 and the electrodes 3a and 3b are covered by a protective film 14. Furthermore, the components of the thin-film resistor 10 except for the terminals 11 are covered by a mold resin 15.

The insulated substrate 2 is made of, for example, ceramics such as an alumina sintered body having electric insulation although the material is not limited. The thin-film resistive element 1 is made of, for example, ruthenium oxide (RuO₂), Cu—Ni or the like. The terminals 11 are formed of a material on which reflow soldering can be performed. The electrodes 3a and 3b are formed of a conductive material having a better electric conductivity than the thin-film resistive element 1. The protective film 14 and the mold resin 15 are molded with, for example, an epoxy-based insulating resin.

It should be noted that FIG. 7 does not show a dummy wire (which is described below) that is a characteristic of this embodiment.

### <Outline of Thin-Film Resistive Element in Comparison Example>

FIG. 8 shows a plan view of a thin-film resistive element in a comparison example. Here, an X direction and a Y direction shown in FIG. 8 indicate two directions that are orthogonal within a surface of the insulated substrate.

The thin-film resistive element 1 is provided on a surface of the insulated substrate 2 shown in FIG. 7, and the thin-film resistive element 1 and the insulated substrate 2 construct the circuit substrate 9 although the insulated substrate 2 is not shown in the figure but the thin-film resistive element 1 is only shown.

As shown in FIG. 8, the thin-film resistive element 1 has a fold-back pattern 1a in which a resistance wire extends in the Y direction and is alternately folded back such that the folded wires face each other at predetermined intervals in the X direction, and wide parts 1e and 1f that are wider than the width of the wiring are provided on both ends of the fold-back pattern. Electrodes 3a and 3b are provided on surfaces of the wide parts 1e and 1f, respectively. As shown in FIG. 8, the electrodes 3a and 3b are disposed at positions away from each other in the X direction.

It should be noted that, as shown in FIG. 8, a resistance pattern 4 for resistance value adjustment is provided between the electrode 3b (wide part 1f) and the fold-back pattern 1a.

### <Problem of Thin-Film Resistive Element in Comparison Example>

Voltage as high as, for example, several hundred V to several thousand V is applied to between the first electrode 3a and the second electrode 3b which are away from each other at both ends in the X direction and have the fold-back pattern 1a therebetween. Thus, near the electrode having a high potential (hereinafter, called “high-potential electrode”), the potential rapidly decreases, and the field intensity is greatly increased. As a result, corrosion easily occurs near the high-potential electrode, which causes a problem that the temporal changes of the resistance value become large.

### <Outline of Thin-Film Resistive Element in First Embodiment>

Accordingly, as a result of keen examinations, the present inventor provides a dummy wire for reducing the field intensity near the high-potential electrode so that the rapid decrease of the potential can be alleviated and the field intensity near the high-potential electrode can be reduced, compared with the comparison example in FIG. 8. As a result, corrosion near the high-potential electrode can be suppressed, and the temporal changes of the resistance value can be small, compared with the comparison example.

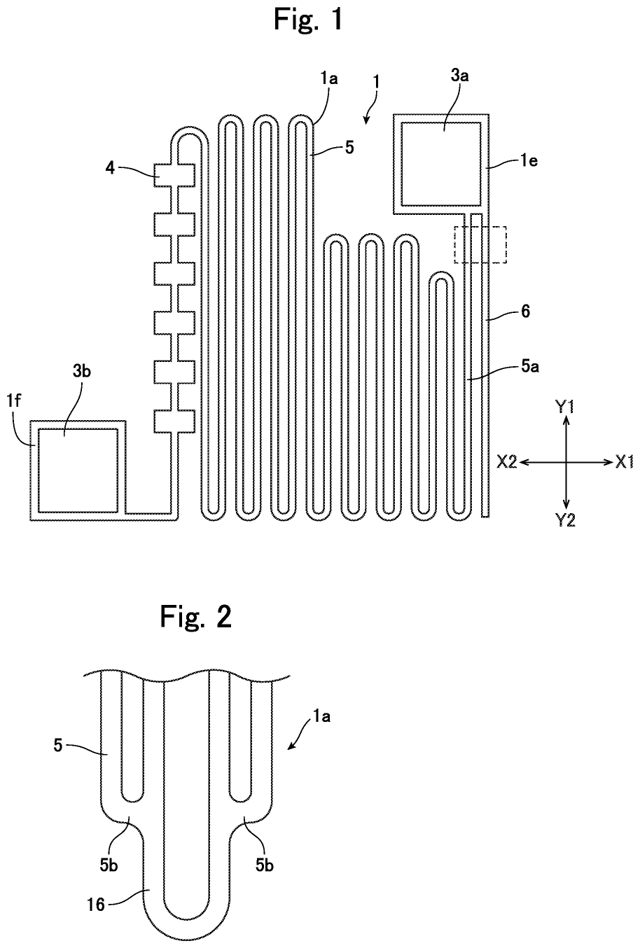

FIG. 1 is a plan view of a thin-film resistive element according to a first embodiment. As shown in FIG. 1, a thin-film resistive element 1 has one fold-back pattern 1a in which a resistance wire 5 extends in a Y1-Y2 direction and is repeatedly folded back at predetermined intervals in an X1-X2 direction orthogonal to the Y1-Y2 direction. Here, the number of turns and the length of extension in the Y1-Y2 direction of the resistance wire 5 can be changed variously in accordance with the resistance value to be required.

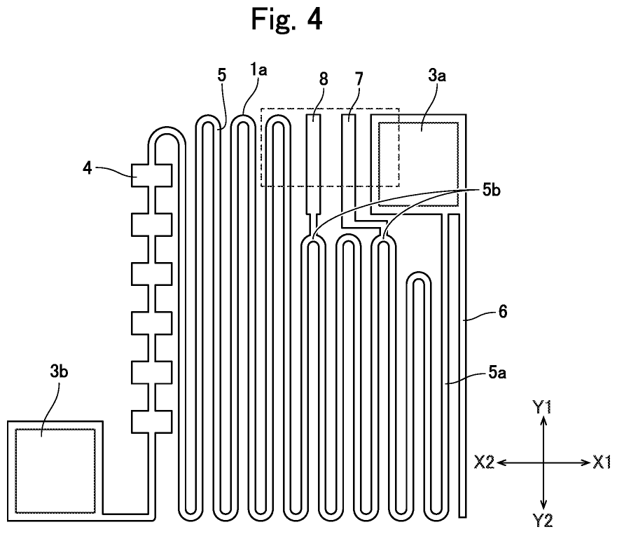

The thin-film resistive element 1 is provided on a surface of the insulated substrate 2 shown in FIG. 7, and the thin-film resistive element 1 and the insulated substrate 2 construct the circuit substrate 9, although the insulated substrate 2 is not shown in the figure and the thin-film resistive element 1 is only shown. The same is true for FIG. 4.

As shown in FIG. 1, wide parts 1e and 1f that are wider than the line width of the resistance wire 5 are provided integrally with the fold-back pattern 1a on both ends in the X1-X2 direction of the resistance wire 5. In other words, the wide parts 1e and 1f are disposed away from each other in the X1-X2 direction orthogonal to the Y1-Y2 direction that is the direction of extension of the resistance wire 5. As shown in FIG. 1, the first wide part 1e is provided at a tip on the Y1 side of the resistance wire 5a positioned outermost on the shown X1 side of the fold-back pattern 1a. On the other hand, the second wide part if positioned on the shown X2 side is provided at an end on the X2 side of the fold-back pattern 1a via a resistance pattern 4 for resistance value adjustment. The resistance pattern 4 is provided integrally with the fold-back pattern 1a and the wide part 1f. The shape and provided position of the resistance pattern 4 can be arbitrarily changed. Resistance adjustment can be performed by trimming the resistance pattern 4.

As shown in FIG. 1, a first electrode 3a is provided on a surface of the first wide part 1e, and a second electrode 3b is provided on a surface of the second wide part 1f. Thus, the electrodes 3a and 3b are disposed away from each other in the X1-X2 direction orthogonal to the Y1-Y2 direction that is the direction of extension of the resistance wire 5. Each of the electrodes 3a and 3b has, but not limited to, a smaller area in some degree than those of the wide parts 1e and 1f.

After a resistive film and an electrode film are formed by sputtering or vapor deposition, all of the resistance wire 5 and the electrodes 3a and 3b can be formed so as to have a predetermined pattern form by using a photolithography technique.

As shown in FIG. 1, the length of extension in the Y1-Y2 direction of the resistance wire 5 decreases in a stepwise manner from the shown X2 side to the shown X1 direction. According to this embodiment, the length of extension of the resistance wire 5 is short such that a space can be provided on the shown X1 side and the shown Y1 side. Thus, the first wide part 1e and the first electrode 3a can be efficiently arranged in the provided space.

Although FIG. 2 shows a part (particularly near the fold vertex) of the fold-back pattern 1a shown in FIG. 1, a resistance pattern 16 for resistance adjustment may be integrally connected between fold vertices 5b of the resistance wire 5 included in the fold-back pattern 1a as shown in FIG. 2. Resistance adjustment can be performed by trimming the resistance pattern 16. In the fold-back pattern 1a shown in FIG. 1, the resistance pattern 16 can be provided at the fold vertices 5b of the resistance wire 5 that is folded back on the shown Y2 side or at the fold vertices 5b of the resistance wire 5 that is folded back on the shown Y1 side. However, preferably, on the shown Y1 side, the resistance pattern 16 is not provided in the resistance wire 5 the length of extension of which decreases in a stepwise manner and that is closer to the first electrode 3a, but is disposed at the fold vertices 5b of the resistance wire 5 the length of extension of which is long and that is away from the first electrode 3a. Thus, resistance adjustment can be easily performed by trimming.

According to this embodiment, as shown in FIG. 1, a dummy wire 6 is provided which is continuous from the resistance wire 5a positioned outermost on the shown X1 side of the fold-back pattern 1a via the first wide part 1e. The dummy wire 6 is folded back to outside of the resistance wire 5a.

According to this embodiment, by providing the dummy wire 6 near the first electrode 3a that is a high-potential side electrode, the decrease of the potential can be alleviated, and the field intensity can be reduced.

Although, referring to FIG. 1, the dummy wire 6 is folded back to outside of the resistance wire 5a positioned outermost, the dummy wire 6 may be folded back to inside. However, folding back the dummy wire 6 to outside provides a sufficient space for the dummy wire 6 so that the dummy wire 6 can be easily formed and that the dummy wire 6 can have a length equal to that of the resistance wire 5a, which can reduce the field intensity more effectively. It should be noted that the dummy wire 6 may be provided on both of the outside and inside of the resistance wire 5a.

The line width of the dummy wire 6 is substantially equal to the line width of the resistance wire 5a in this embodiment although the line width of the dummy wire 6 is not limited.

### <Outline of Thin-Film Resistive Element in Second Embodiment>

Next, with reference to FIG. 4, a pattern in a thin-film resistive element according to a second embodiment is described.

In an embodiment shown in FIG. 4, dummy wires 7 and 8 branch off from the resistance wire 5 constructing the fold-back pattern 1a. It should be noted that the dummy wires 7 and 8 are called branch type dummy wires 7 and 8 below.

As shown in FIG. 4, the branch type dummy wires 7 and 8 are provided near the first electrode 3a that is a high-potential electrode, and according to this embodiment, extend to a position facing the first electrode 3a in the X1-X2 direction. Both of the branch type dummy wires 7 and 8 branch off from the fold vertices 5b of the resistance wire 5 to the Y1 direction. The length of extension in the Y1-Y2 direction of the resistance wire 5 decreases in a stepwise manner toward the shown X1 direction so that a space is provided near the first electrode 3a. Thus, by using this space, the branch type dummy wires 7 and 8 can branch off from the fold vertices 5b of the resistance wire 5 and can extend to a position facing the first electrode 3a in the X1-X2 direction. Therefore, the branch type dummy wires 7 and 8 can be formed reasonably and such that the effect of reduction of the field intensity can be effectively exerted.

According to this embodiment, the branch type dummy wires 7 and 8 are provided near the first electrode 3a that is the high-potential side electrode so that the decrease of the potential can be alleviated and the field intensity can be reduced.

In the embodiment in FIG. 4, the dummy wire 6 is folded back on the outside of the resistance wire 5a positioned outermost of the fold-back pattern 1a, like the one in FIG. 1. Thus, more effectively, the decrease of the potential can be alleviated, and the field intensity can be reduced.

However, referring to FIG. 4, the dummy wire 6 may not be provided, and only the branch type dummy wires 7 and 8 may be provided.

The branch type dummy wires 7 and 8 shown in FIG. 4 having a substantially equal line width to that of the resistance wire 5 branch off from the fold vertex 5b of the resistance wire 5, and the branch type dummy wires 7 and 8 in the part facing the first electrode 3a in the X1-X2 direction have a wide line width, but the line widths of the branch type dummy wires 7 and 8 are not limited thereto.

A plurality of dummy wires are preferably provided so that, more effectively, the decrease of the potential can be alleviated and the field intensity can be reduced.

A potential distribution and a field intensity distribution of a part enclosed by a dashed line of the embodiment shown in FIGS. 1 and 4 are described below.

### <Potential Distribution and Field Intensity Distribution>

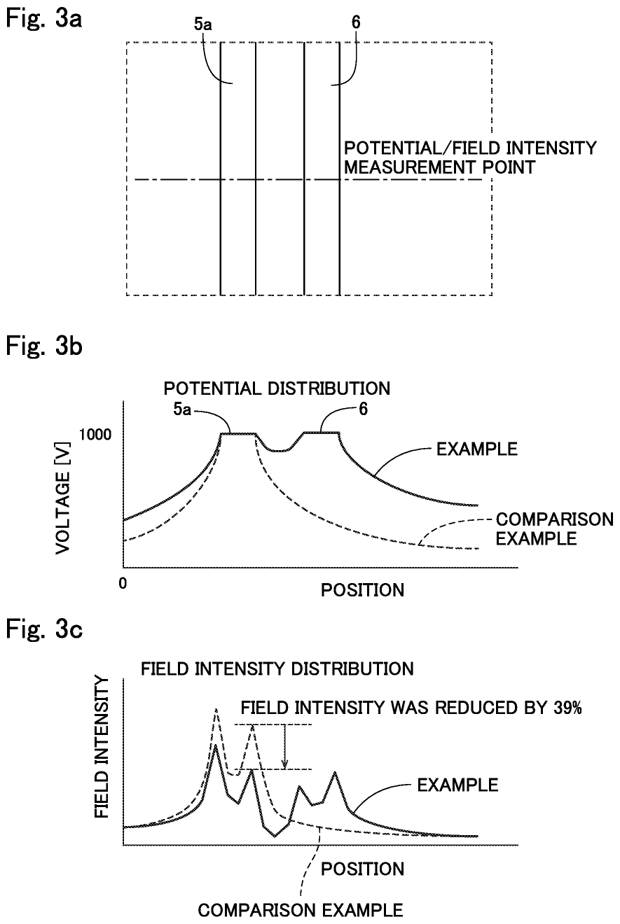

FIG. 3(a) is an enlarged view of the part enclosed by the dashed line shown in FIG. 1. FIG. 3(a) shows the resistance wire 5a positioned outermost of the fold-back pattern 1a and the dummy wire 6 folded back to outside of the resistance wire 5a with a space therebetween.

FIG. 3(b) shows a potential distribution when voltage of 1000 V is applied to between the electrodes 3a and 3b. It should be noted that the potential distribution in FIG. 3(b) is a distribution diagram at a potential measurement point indicated by an alternate long and short dashed line in FIG. 3(a).

A solid line shown in FIG. 3(b) is a potential distribution diagram of an example including the dummy wire 6, and a dashed line therein is a potential distribution diagram without the dummy wire 6 in the comparison example in FIG. 8. As shown in FIG. 3(b), in the comparison example, it was found that the potential rapidly decreased on both sides of the resistance wire 5a. On the other hand, in the example, it was found that, because of the dummy wire 6, the potential at the position where the dummy wire 6 is provided could be increased, and compared with the comparison example, the decrease of the potential on both sides of the resistance wire 5a could be effectively alleviated.

FIG. 3(c) shows a field intensity distribution. It should be noted that the field intensity distribution in FIG. 3(c) is a distribution diagram at the field intensity measurement point indicated by the alternate long and short dashed line in FIG. 3(a). A solid line shown in FIG. 3(c) is a field intensity distribution diagram of the example including the dummy wire 6, and a dashed line therein is a field intensity distribution diagram without the dummy wire 6 in the comparison example in FIG. 8.

As shown in FIG. 3(c), it was found that, in the example, the field intensity could be reduced more than the comparison example, and that, in the simulation result, the field intensity could be reduced by about 39% compared with the comparison example.

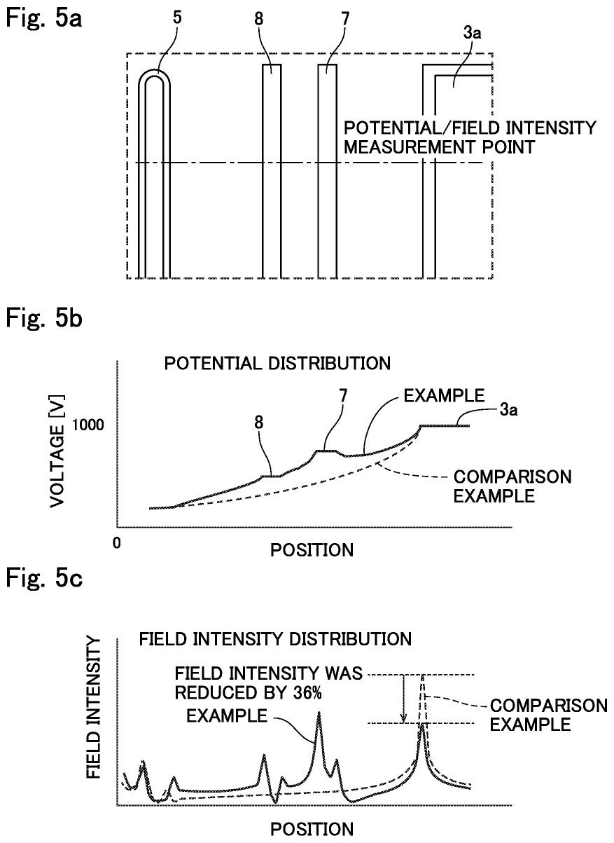

Next, FIG. 5(a) is an enlarged view of the part enclosed by a dashed line shown in FIG. 4. FIG. 5(a) shows the first electrode 3a, the resistance wire 5, and the branch type dummy wires 7 and 8 positioned between the first electrode 3a and the resistance wire 5.

FIG. 5(b) shows a potential distribution when voltage of 1000 V is applied to between the electrodes 3a and 3b. It should be noted that the potential distribution in FIG. 5(b) is a distribution diagram at the potential measurement point indicated by an alternate long and short dashed line in FIG. 5(a).

A solid line shown in FIG. 5(b) is a potential distribution diagram of an example including the branch type dummy wires 7 and 8, and a dashed line therein is a potential distribution diagram without the branch type dummy wires 7 and 8 in the comparison example in FIG. 8. As shown in FIG. 5(b), it was found that, in the comparison example, the potential rapidly decreased near the first electrode 3a. On the other hand, it was found that, in the example, because of the branch type dummy wires 7 and 8, the potential could be increased at the positions where the branch type dummy wires 7 and 8 were provided, and compared with the comparison example, the potential decrease near the first electrode 3a could be effectively alleviated.

FIG. 5(c) shows a field intensity distribution. It should be noted that the field intensity distribution in FIG. 5(c) is a distribution diagram at the field intensity measurement point indicated by the alternate long and short dashed line in FIG. 5(a). A solid line shown in FIG. 5(c) is a field intensity distribution diagram of an example including the branch type dummy wires 7 and 8, and a dashed line therein is a field intensity distribution diagram without a dummy wire in the comparison example in FIG. 8.

As shown in FIG. 5(c), it was found that, in the example, the field intensity could be reduced more than the comparison example, and in the simulation result, the field intensity could be reduced by about 36% compared with the comparison example.

<Regarding Improvement Effect>

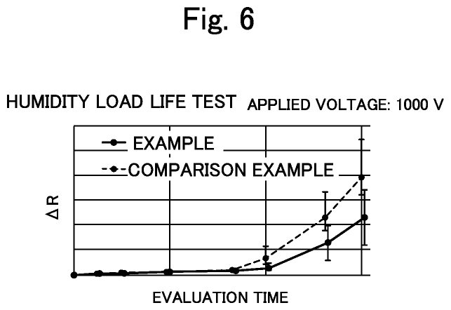

Next, an improvement effect of the example is described. FIG. 6 is a graph showing a relationship between evaluation time and AR in humidity load life tests according to an example and a comparison example. In the example, an experiment was performed by using the thin-film resistive element shown in FIG. 4. In the comparison example, an experiment was performed by using the thin-film resistive element shown in FIG. 8.

In the experiments, applied voltage was 1000 V, and temporal changes of the resistance value were measured under an environment with a temperature of 85° C. and a humidity of 85%.

As shown in FIG. 6, it was found that the changes of the resistance value could be smaller in the example than the comparison example. This is because, in the example, the field intensity can be reduced compared with the comparison example, and corrosion can be suppressed. In this way, in the example, it was found that the changes of the resistance value could be small and an increase in product life could be promoted.

According to the experiment, ion migration did not occur in the comparison example, and corrosion of metal was a problem. The resistance pattern used in the experiment was a structure having electrodes on both sides of a fold-back pattern in which a resistance wire is repeatedly folded back. Furthermore, the resistance wire extends in the Y1-Y2 direction and is repeatedly folded back at intervals in the X1-X2 direction orthogonal to the Y1-Y2 direction, and the electrodes are disposed away from each other on the both sides in the X1-X2 direction. When high voltage is applied to between the electrodes in the pattern arrangement, corrosion of metal is a problem with an increase in field intensity near the high-potential electrode. Accordingly, in the example, a dummy wire for attempting reduction of the field intensity was provided near the high-potential electrode so that occurrence of corrosion was suppressed.

### INDUSTRIAL APPLICABILITY

With the thin-film resistive element of the present invention, the field intensity can be reduced, and temporal changes of the resistance value can be small. The circuit substrate having the thin-film resistive element of the present invention is applicable to a chip resistor, a resistance network and the like.

### REFERENCE SIGNS LIST

1 Thin-film resistive element
1a Fold-back pattern
1e, 1f Wide part
2 Insulated substrate
3a, 3b Electrode
4, 16 Resistance pattern
5, 5a Resistance wire
5b Fold vertex
6 Dummy wire
7, 8 Branch type dummy wire
9 Circuit substrate
10 Thin-film resistor
11 Terminal
12 Wire
13 Die pad
14 Protective film
15 Mold resin

1. A circuit substrate comprising an insulated substrate, a thin-film resistive element, and electrodes electrically connected to both sides of the thin-film resistive element, the thin-film resistive element and the electrodes being disposed on a surface of the insulated substrate, characterized in that
the thin-film resistive element has a pattern in which a resistance wire is repeatedly folded back, and
a dummy wire for reducing a field intensity is provided on a high-potential electrode side.

2. The circuit substrate according to claim 1, characterized in that the dummy wire is provided continuously to the fold-back pattern of the resistance wire.

3. The circuit substrate according to claim 2, characterized in that the dummy wire is folded back to outside from the resistance wire positioned outermost of the fold-back pattern.

4. The circuit substrate according to claim 1, characterized in that the dummy wire branches off from the resistance wire.

5. The circuit substrate according to claim 4, characterized in that the dummy wire branches off from a fold vertex of the resistance wire.

6. The circuit substrate according to claim 1, characterized in that a plurality of the dummy wires are provided.
